(19) United States
(12) Patent Application Publication
(10) Pub. No.: US 2012/0132188 A1
(43) Pub. Date: May 31, 2012

(54) HOLDING/CLEANING DEVICE AND METHOD FOR THE ZONAL CLEANING OF SAWED WAFERS

(75) Inventor: Roland Dechant-Wagner, Villingen-Schwenningen (DE)

(73) Assignee: RENA GMBH, Gutenbach (DE)

(21) Appl. No.: 13/299,076

(22) Filed: Nov. 17, 2011

(30) Foreign Application Priority Data
Nov. 29, 2010 (DE) 10 2010 052 635.5

(51) Int. Cl. H01L 21/304; B28D 5/00; B28D 7/04; B28D 7/02

(52) U.S. Cl. 125/35; 134/42

(57) ABSTRACT

A device for holding a substrate block to be sawed and for flushing the intermediate spaces formed by sawing the substrate block. It comprises two regions arranged parallel to the device longitudinal axis and above one another, the upper region being configured as an adapter region by means of which the device can be connected to a machine instrument, and the lower region being formed as a holding region which comprises a circumferentially closed or closable channel system which can be supplied with flushing liquid by means of closable supply openings and the bottom of which is opened in a slot-like fashion during the sawing of the substrate block so as to provide passage openings for the flushing liquid. A method for flushing intermediate spaces formed by sawing a substrate block using the above device.

### CROSS REFERENCE TO RELATED APPLICATIONS

This invention claims benefit of priority to German patent application no. 10 2010 052 635.5, filed Nov. 29, 2010; the contents of which are herein incorporated by reference in their entirety.

### TECHNICAL FIELD

The invention relates to a device for the combined holding and cleaning of flat substrates which are produced from a block by means of sawing, and to a method therefor. In particular, the invention relates to the holding and cleaning of flat silicon substrates, also referred to below as wafers for brevity, which have been sawed from a block, also referred to as an ingot, of mono- or polycrystalline silicon.

### INTRODUCTION

The term “wafers” is intended according to the invention to mean slice-like objects which have a very small thickness in comparison with their other dimensions, which typically lies in the range of between 80 and 300 μm and, in particular, between 150 and 170 μm. In contrast, the lateral dimensions are for example 125×125 mm (5 inch wafers) or more. The shape of the slices is arbitrary and may, for example, be essentially round (semiconductor wafers) and have an optional edge which indicates the crystal orientation (wafer flat), or be essentially rectangular or square (solar wafers), in which case the corners may optionally be angled, rounded or chamfered. The described objects are very fragile owing to the combination of small thickness and low elasticity.

### PRIOR ART AND DISADVANTAGES

In order to produce the wafers, the block is first fixed on a support plate. This typically consists of glass and is flat or curved depending on the shape of the block. An adhesive is conventionally used for the fixing. The support plate is for its part fitted on an adapter plate, which typically consists of metal. The adapter plate is configured so that it cooperates with a backing face which is part of the cutting device (wafer saw). After the adapter plate has been fastened on the backing face, the block can be processed with the cutting device, for example a wire saw, which typically comprises one or more cutting wires extending parallel. Thin slices are thereby produced from the block, which because of the adhesive are suspended from the support plate by their edge facing toward the support (adhesive edge). The successively arranged slices are therefore still connected to one another by means of the support plate. For full separation of a wafer from the block, the cutting device must cut some way into the support plate, which is thereby incised and is therefore unsuitable for reuse.

After a lengthwise section of the block has been fully divided into individual wafers and a laminar intermediate space has therefore been formed between the individual wafers, this lengthwise section is in the form of a comb-like structure in the shape of a fan, which is also referred to as a “wafer comb”. The wafer comb is preferably handled in the orientation in which it is suspended from the support plate, which also applies in particular for the subsequent cleaning steps.

For reasons of economy, it is common practice for a plurality of short blocks to be adhesively bonded successively on a support plate and subsequently sawed. This obviates repeated clamping and release of the workpieces.

In order to remove the waste particles, the sawing process involves a suspension referred to as a slurry, which typically consists of carrier liquid and optionally silicon carbide as well as further additives. This suspension undesirably adheres to the wafer surface, and becomes fixed in the intermediate spaces. This applies both when silicon carbide is used as a cutting medium and in cases in which diamond-coated sawing wires are employed. For further processing, the sawed wafers must be both removed from the adhesive layer and separated, as well as cleaned. Cleaning, or in any event precleaning, should in this case be carried out as early as possible, in particular even before the adhesive is removed. This avoids increased adhesion of the slurry, which is very solid in the dried state. The streaks which the slurry forms on the edges once it has dried also become almost impossible to remove and in the extreme case can lead to unusability of the wafer. The slurry furthermore contaminates subsequent process baths by being transferred, which is likewise undesirable.

A cleaning device for such wafers still fastened to the holding plate is presented, for example, in the document WO 2009/074297 A2. Here, the fully sawed block is flushed by means of a spray instrument arranged laterally with respect to the sawed block. The jet of cleaning liquid is in this case directed laterally into the laminar intermediate spaces. A problem with this is the fact that the central region of the adhesive edge can be reached only insufficiently. This leads either to a correspondingly long cleaning time or to incomplete precleaning. In order to improve the cleaning result, alternate spraying from both sides, relative mobility of the support and the spray instrument and assistance by gas bubbles and/or ultrasound are proposed. Document EP 1935514, which is based on the aforementioned document, additionally proposes tilting mobility of the spray instrument. Even then, however, the problem mentioned above is not satisfactorily resolved.

In order to overcome the problem of poor flushability, EP 2153960 A2 proposes to provide at least one passage for delivering a flushing fluid between the wafers suspended from the support. Because of the application to the passage after the sawing, the flushing fluid emerges through a single longitudinal gap, through a plurality of transverse gaps or through bores of the passage, in the direction of the intermediate spaces of the wafer comb. The aforementioned residues are therefore cleaned from them in their entirety. The longitudinal gap, the transverse gaps or bores in the passage are in this case typically present in the support at all times, that is to say also before and after only partial sawing of the block. As an alternative, the transverse gaps may also be produced only as a result of the sawing process itself. In this case, the material forming the passage typically consists of a softer material than the rest of the device, in order to stress the sawing wire as little as possible during the incision.

Owing to the fact that cleaning fluid can only be applied to the passage as a whole, it emerges simultaneously in the direction of the wafer intermediate spaces through the entire longitudinal gap or the bores, or through the transverse gaps formed by the sawing. This sometimes results in a nonuniform cleaning effect, since the pressure and therefore the fluid volume flowing out decrease with an increasing length of the passage. The nonuniform cleaning effect resulting from this, and the loss of unused cleaning fluid, are unsatisfactory. In order to be able to ensure effective use of the cleaning fluid, the cleaning must be carried out with a lance or the like. Only locally in the region of the lance tip is the pressure drop minimal and the volume flow maximal, and therefore the desired cleaning effect achievable. By moving the lance tip over the longitudinal extent of the passage, the cleaning of the respective wafer intermediate spaces is essentially carried out sequentially and therefore time-intensively. Furthermore, an elaborate technology is required for the device necessary for this. A technically simpler solution involves pressing external supply nozzles onto the corresponding connection opening of the passage, in order to achieve a sufficient sealing effect for the passage. Owing to the soft material used there (see above), however, damage to the connection opening often occurs since the pressure and volume flow must be high because of the continuous passage. Another disadvantage resides in the fact that, in cases in which merely a section of the support is connected to a block, cleaning fluid nevertheless emerges over the entire length of the supply. This also leads to ineffective use of the cleaning fluid.

### BRIEF SUMMARY OF THE INVENTION

It is therefore an object of the invention to ensure uniform distribution and effective use of the cleaning liquid over the entire longitudinal extent of the support. Application of the cleaning liquid should optionally be possible even while the block is present in the saw, without the risk of interfering with the sawing process. The device required for achieving these objects should be as simple as possible.

The object is achieved by a device for holding a substrate block to be sawed and for flushing the intermediate spaces formed by sawing the substrate block, having two regions arranged parallel to the device longitudinal axis and above one another, the upper region being configured as an adapter region by means of which the device can be connected to a machine instrument, and the lower region being formed as a holding region which comprises a part, provided as a channel, of a circumferentially closed or closable channel system which can be supplied with flushing liquid by means of closable supply openings, the bottom of the channel being opened in a slot-like fashion during the sawing of the substrate block so as to provide passage openings for the flushing liquid, and the channel being subdivided into a plurality of sections along the device longitudinal axis.

The object is also achieved by a cleaning method, which provides a method for flushing the intermediate spaces formed by sawing a substrate block by using the device, wherein a flushing liquid is applied to the channel system and emerges therefrom via the passage openings. Preferred embodiments may be found in the following description and in the drawings.

### BRIEF DESCRIPTION OF THE DRAWINGS

FIG. 1 shows an external view of a preferred embodiment of the device according to the invention.

FIG. 2 shows a sectional view of the device according to FIG. 1.

FIG. 3 shows a further sectional view of the device according to FIGS. 1 and 2 with a substrate block.

FIG. 4 shows an embodiment of the device according to the invention with a differently configured adapter plate.

### DETAILED DESCRIPTION

The device according to the invention will be described in more detail below. This is followed by a description of the method according to the invention.

The device according to the invention is used for holding a substrate block to be sawed and for flushing the intermediate spaces formed by sawing the substrate block, with two regions arranged parallel to the device longitudinal axis and above one another, the upper region being configured as an adapter region by means of which the device can be connected to a machine instrument, and the lower region being formed as a holding region which comprises a circumferentially closed or closable channel system which can be supplied with flushing liquid by means of closable supply openings and the bottom of which is opened in a slot-like fashion during the sawing of the substrate block so as to provide passage openings for the flushing liquid.

The holding according to the invention is preferably carried out in a position in which the substrate block, or the substrates produced therefrom, are arranged suspended. These objects are particularly preferably fastened to the device according to the invention by means of an adhesive layer. As an alternative or in addition, clamping of the objects is also possible.

Even though the device is primarily used for flushing the aforementioned intermediate spaces, it can also be used for cleaning or at least precleaning the surfaces of the sawed substrates. Typically, however, such cleaning is carried out by means of other devices (cf. comments above regarding the prior art).

The sawed substrates are arranged successively in the device longitudinal axis after the sawing. The device longitudinal axis therefore extends in the direction of the surface normals of the substrates. Typically, the device has a length which is greater than the width of the device. It therefore has an upper and lower flat side, a front and rear end side, as well as a left and right side.

The position designations of the “upper” and “lower” region in this case merely serve for orientation according to the description. The device may also be constructed the other way round, without departing from the inventive concept. The term “above one another” means that the two regions respectively have at least one surface which is larger in relation to the other external surfaces (side surfaces). The two regions can therefore be contiguous at this surface.

The “adapter region” is configured so that it can be fitted to a machine instrument, in particular the forward movement instrument of a wafer saw. It is clear that this region may have geometrical features particularly preferably corresponding thereto, such as directionally positioned holes/bores, stops, recesses for rail guiding, etc. It is likewise preferable for this region to be made of a hard, solid and both mechanically and chemically stable material, for example stainless steel or ceramic.

The “holding region” is used for fastening the device to the substrate block (see above). It should be mentioned that initially only two functionally different regions are then involved, so that the device per se can readily be produced in a single piece.

According to the invention, the holding region comprises a channel system through which flushing liquid can be delivered in the direction of the aforementioned intermediate spaces. The term “channel system” means that there may be a single continuous channel or a multiplicity of mutually independent individual channels. It is clear that the channel system must have supply openings, through which the flushing liquid can flow into the channel system. According to the invention there are a plurality of these supply openings, although they are closable. In this way, the position at which the cleaning liquid is fed into the channel system is flexibly selectable. The aforementioned closability is provided so that the cleaning liquid does not emerge from the channel system at an undesired position. In principle, a circumferentially closed channel system may thereby be produced, “circumferentially” meaning the two sides as well as the front and rear end faces of a substantially flatly formed device according to the invention. It does not, however, mean the upper and lower sides of the device. It is also clear that the supply bores should not be arranged on the side (lower side of the device) facing toward the substrate block. It should furthermore be mentioned that the channel system need not be arranged exclusively in the holding region. It may readily also comprise sections which extend in the upper region. It is even possible for the channel system to be open toward the adapter region, and for it to be correspondingly sealed and therefore become a “channel system” only when fitted to the machine instrument. What is essential is merely that the channel system comprises sections which project into the holding region and are suitable for conveying the cleaning liquid to the desired positions on the outside of the holding region. These positions lie in the bottom of the channel system, i.e. in the region which faces toward the outside of the holding region. The positions are opened according to the invention when sawing the substrate block, in order to provide passage openings for the flushing liquid.

The described use, according to the invention, of a circumferentially closable or closed channel system results in a more uniform effect of flushing the intermediate spaces, since cleaning liquid no longer emerges from the channel system at an undesired position. The pressure is essentially constant inside the channel system, and the emerging volume flow therefore no longer decreases with an increasing distance from the supply opening. This results in a more uniform flushing effect, and the loss of unused flushing liquid is significantly less. The pressure to be applied can be low in comparison with a passage which is open (on both sides). The movement of a lance tip over the longitudinal extent of a supply channel, as is known from the prior art, is obviated, as is the liquid loss due to the movement gap necessary because of its mobility.

According to the invention, it is particularly preferable for the channel system to comprise a plurality of sections along the device longitudinal axis, which can be supplied independently of one another with flushing liquid. In other words, flushing liquid can be individually applied to a particular section of the device, which is preferably a lengthwise section, independently of one or more other sections. This provides, inter alia, the advantage that the loss of flushing liquid can be reduced further if a substrate block which does not extend over the entire length of the device is to be flushed.

According to one embodiment, the sections are formed by a plurality of structurally separate channels which can be supplied independently of one another. These channels may be arranged next to one another, but preferably behind one another as seen in the device longitudinal axis. The supplies in this case lead to separate supply openings. These are in turn preferably arranged on the same side of the device, for example on the rear end face.

According to one embodiment, the sections are formed by liquid-blocking barriers fitted removably in the channel system. This means that an initially continuous channel, which in turn preferably extends in the device longitudinal axis, can be interrupted by objects which can be fitted into the channel at different positions, preferably at arbitrary positions of its longitudinal extent. The channel particularly preferably has positive or negative geometrical features on its inner wall, such as projections or machined insets, with which the objects interact with a form fit. Interaction by force fit on an e.g. smooth channel inner wall may also be envisaged. To this end, the objects may particularly preferably be formed so that they are flexible. For example, they may consist of or comprise resilient material, or permit the force fit by means of a clamp mechanism or spring mechanism. Of course, combinations of the two variants (force and form fit) are also possible.

According to a particularly simple embodiment, the channel in question has projections, approximately triangular in plan view, facing toward the channel interior of its inner wall, which engage in corresponding recesses of the objects which otherwise have the form of a flat platelet. According to another similar embodiment, the objects themselves have corresponding projections.

According to a preferred embodiment, the closable supply openings are arranged on the upper flat side of the adapter region. According to the invention, this side faces in the direction of the machine instrument. Accordingly, the machine instrument itself bears correspondingly arranged openings, from which the flushing liquid can be delivered. In this way, particularly simple fluidic coupling of the device according to the invention to the external supply lines is possible. It is clear that the positions of the openings of the machine instrument must at least partially coincide with the supply openings of the device according to the invention. It is also clear that seals may be fitted into the supply openings and/or the openings in the machine instrument for the purpose of improved leaktightness.

According to another embodiment, the outside connections of the closable supply openings are arranged on the circumferential side of the adapter region. This comprises the front and rear end sides and the right and left sides of the device. Here again, it should be mentioned that the supply openings are particularly preferably arranged in the adapter region and not in the holding region. The advantage of this arrangement resides in the fact that the material of which the holding region consists may sometimes be less strong than the material of the adapter region. Arranging the supply openings in the adapter region ensures that they are located in a material suitable for mechanical processing and stress. It is clear that channel sections extending suitably inside the device are provided, which lead from the supply openings arranged in the adapter region to the channel system preferably extending in the holding region. It is also clear that for zonal suppliability of a channel, or for separate suppliability of individual channels, correspondingly separate supply openings must be provided.

As an alternative or in addition to the embodiments above with zonal suppliability, the supply may however take place through a single supply opening, with valves, gates and the like which are arranged inside the device according to the invention and can be actuated or controlled from the outside, making it possible to direct the flushing liquid flow into the desired channels or channel sections.

According to one embodiment, the holding region is arranged on a holding plate and the adapter region is arranged on an adapter plate, and the two plates are connected releasably to one another. In other words, according to this embodiment the hitherto purely functional separation of the adapter region and the holding region is also reflected by the provision of two separate components. It is clear that these components must be connected firmly to one another in order to fulfill their function. It is likewise clear that releasability is provided, so that the part of the device which is “consumed” when sawing the substrate block, namely the holding region, can easily be replaced. Furthermore, simple accessibility of the channel system is possible in this way. Therefore, according to requirements, an individual configuration of the channel sections is possible which is tailored to fitting with individual substrate blocks of different length.

According to another embodiment, the material of the holding region, and of the holding plate if there is one, is selected from the group consisting of glass, plastic, epoxide, ceramic, metal and mixtures thereof. It is particularly preferable to use glass, plastic or epoxide. The use of metal is less preferred, since this material is usually less easy to saw than the other materials mentioned. What is essential is that the material is easy to saw, that the sawing does not form any particles which interfere with the processing operation or compromise the result, that the material is strong enough to withstand the mechanical stresses when bonding and sawing the substrate block, and that the production costs are as low as possible.

Besides a device, the invention also relates to a method for flushing the intermediate spaces formed by sawing a substrate block by using a device as disclosed in the scope of the description above, wherein a flushing liquid is applied to the channel system and emerges therefrom via the passage openings.

A device which is particularly suitable for carrying out the method according to the invention accordingly comprises two regions arranged parallel to the device longitudinal axis and above one another, the upper region being configured as an adapter region by means of which the device can be connected to a machine instrument.

In the lower region used as a holding region, a circumferentially closed channel system is arranged and is supplied with flushing liquid by means of closable supply openings in a first step.

In a second step, the intermediate spaces are flushed by means of slot-like passage openings for the flushing liquid, which have been formed in the bottom of the channel system when sawing the substrate block.

In order to avoid repetition concerning the device components, reference is moreover made to the description given above of the device according to the invention.

According to the invention, the flushing takes place uniformly along the device longitudinal axis via the passage openings supplied with flushing liquid. This is a consequence of the fact that a uniform pressure is built up in the circumferentially closed channel system, which leads to uniform exit of the flushing liquid from the slot-like openings intended therefor.

According to a particularly preferred embodiment, the supply of the channel system and the flushing by means of the passage openings take place zonally as seen in the device longitudinal axis. This means that not all of the channel system and therefore all the passage openings connected to it are used simultaneously for the flushing, but rather that parts of the channel system are flushed with liquid according to requirements, so as to permit controlled flushing of substrate blocks or substrate groups produced therefrom, which have a shorter length than the device itself.

The zonal flushing may optionally be achieved by providing a plurality of supply openings to which cleaning liquid can be applied separately, and/or by providing instruments inside the device which make it possible to select the respectively desired channel or channel section.

According to another embodiment, the flushing is carried out in the working region of a wafer saw. This means that an additional device for (pre)cleaning is not required, which saves on costs.

The otherwise necessary transport of the sawed substrates into the corresponding (pre)cleaning apparatus is furthermore obviated, which saves time. According to an alternative embodiment, however, the flushing is carried out in a subsequently arranged separate flushing tank of a flushing device.

According to a particularly preferred embodiment, the flushing is carried out during extraction of the sawing wire of the wafer saw from the intermediate spaces. The one or more sawing wires provided accordingly act as spacers so that the substrates do not adhere together after the sawing. This also ensures that the sawing gap remains open, which permits effective flushing. The flushing may in this case be carried out during extraction of the sawing wire, or during a temporary pause in the extraction.

According to another embodiment, the flushing is carried out in a liquid and/or with ultrasound assistance. Cold or warm water, or an aqueous solution which dissolves or dilutes the slurry, may in particular be envisaged as the liquid. If provided, the ultrasound sources are particularly preferably adapted so that they are directed toward the intermediate spaces of the substrates.

The device described above and the method described above allow a uniform effect of cleaning a wafer comb still in the sawing device. This saves on time and cleaning liquid. The flushing process takes place more effectively and more economically than according to the prior art. The device according to the invention is simply constructed and can therefore be produced and operated economically. Damage to the soft support region is avoided, since no supply bores need to be formed therein.

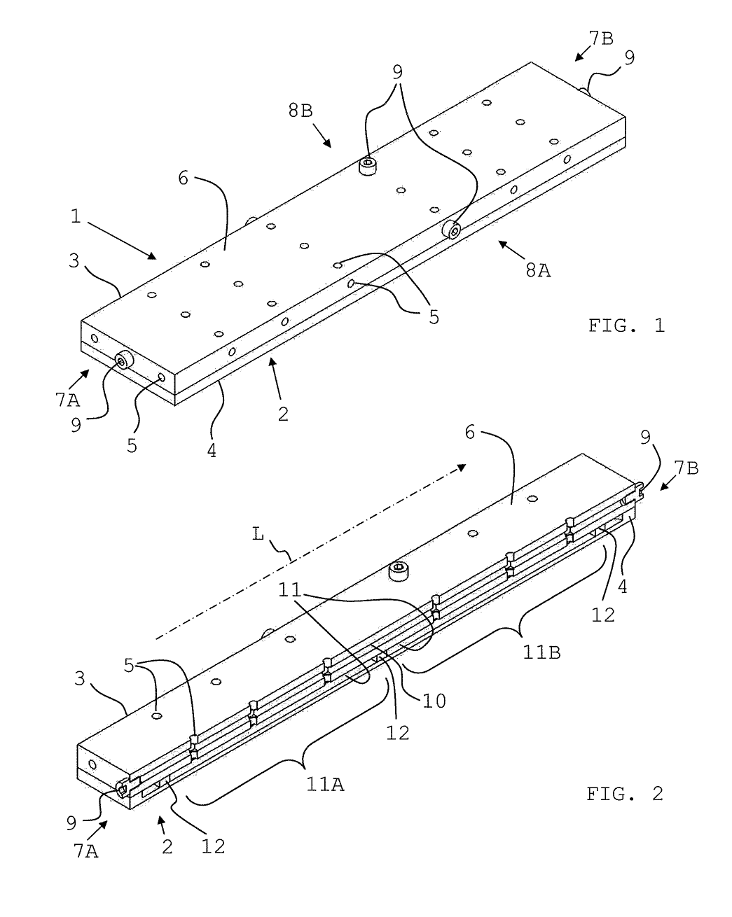

Turning now to the drawings, FIG. 1 represents the device according to a preferred embodiment in perspective view. The device comprises an upper region used as an adapter region 1, and a lower region used as a holding region 2 for one or more substrate blocks (not shown). Here, the adapter region 1 is located on the side, facing upward in the image, of an adapter plate 3 provided as a separate component, and the holding region 2 is located on a holding plate 4 likewise provided as a separate component. The figure furthermore shows a multiplicity of supply openings 5 (only some of which are provided with references). The supply openings 5 in the present case are arranged on the upper flat side 6, on the front and rear end sides 7A, 7B and on the right and left sides 8A, 8B of the device. All the supply openings 5 are located in the adapter region 1, or in the adapter plate 3. Some of the supply openings 5 are closed by means of closure screws 9. FIG. 2 shows a sectional view, extending along the device longitudinal axis L (dot-and-dash arrow), of the device described here. The function of the closure screws 9 arranged on the end sides 7A, 7B can be seen clearly. They close a channel 10, here extending through the entire device, which is part of a branched channel system. The latter can be supplied with flushing liquid (not shown) through the supply openings 5 (some of which are without references in FIG. 2). The embodiment represented is provided merely for illustration with a few closure screws 9; in the normal case, most of the closable supply openings 5 are in fact closed, so that the flushing liquid cannot emerge at an undesired position.

As can be seen, the channel system is also provided in the form of a channel 11 in the holding region 2, or in the holding plate 4. There, in the present case, it can be supplied by means of the channel 10 and by means of supply openings 5, which are located in the upper flat side 6 of the adapter plate 3. This part of the channel system comprises two sections 11A, 11B. Depending on the position of the closure screws 9, the latter can be supplied separately from one another. In order to form these two sections 11A, 11B, liquid-blocking barriers 12 fitted removably in the channel system are provided in the corresponding part of the channel system (channel 11). With these, it is correspondingly possible to subdivide the channel 11 which initially extends through almost all of the device. The positions of the barriers can be determined flexibly according to requirements when assembling the device.

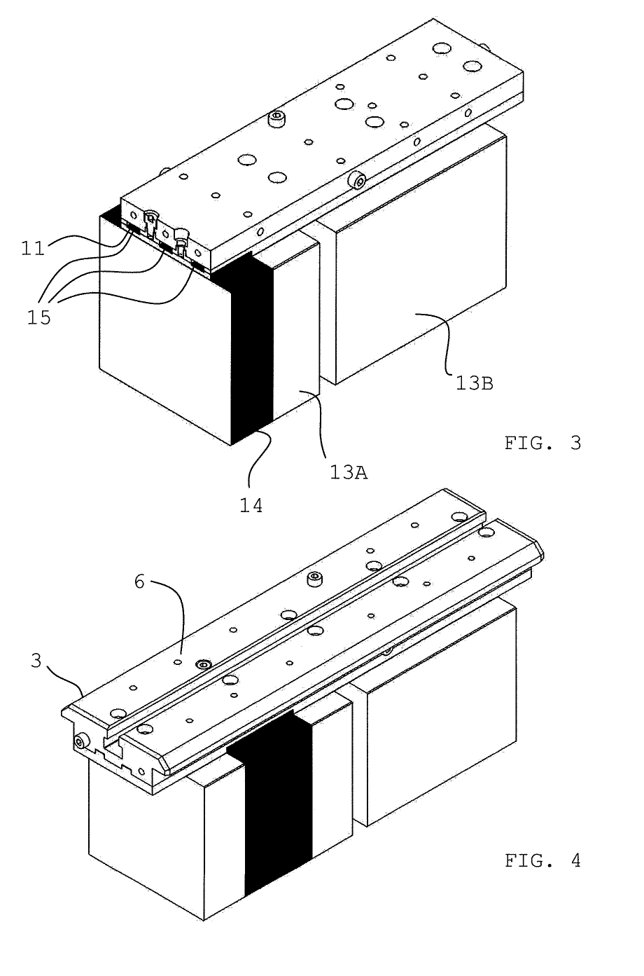

FIG. 3 shows a frontal sectional view of the device according to FIGS. 1 and 2. Two substrate blocks 13A, 13B are furthermore represented, which are arranged suspended from the device according to the invention. The rear substrate block 13B has not yet been sawed, while the front substrate block 13A has already been partially sawed into individual substrates 14 (region with black side face). As can be seen in FIG. 3, there are now passage openings 15 in the channel 11. The passage openings 15 have been produced when sawing the substrate block 13A into the substrates 14 by means of a sawing wire (not shown). If flushing liquid (not shown) is applied to the channel system, by supplying it by means of the supply openings (not provided with references), the flushing liquid emerges from the passage openings 15. From there, it flows into the region of the intermediate spaces of the substrates 14, where it flushes out any slurry which may be present. Since the intermediate spaces are open toward the sides and downward, the flushing liquid loaded with slurry can flow away unimpeded.

According to FIG. 4, the adapter plate 3 may also be configured in a manner different to that represented here. It may, as shown, comprise a reception rail 16, by which the device can be connected (not shown) to a machine instrument. It is clear that a geometry other than that shown for the upper flat side 6 of the adapter plate 3 may also be provided, depending on the specific configuration of the machine instrument.

### LIST OF REFERENCES

1 adapter region
2 holding region
3 adapter plate
4 holding plate
4 supply openings
6 upper flat side
7A front end side
7B rear end side
8A right side
8B left side
9 closure screw
10 channel
11 channel
11A first section
11B second section
12 barrier
13A substrate block
13B substrate block
14 substrate
15 passage openings
16 reception rail
L device longitudinal axis

What is claimed is:

1. A device for holding a substrate block (13A, 13B) to be sawed and for flushing the intermediate spaces formed by sawing the substrate block (13A, 13B), having two regions arranged parallel to the device longitudinal axis (L) and above one another, the upper region being configured as an adapter region (1) by means of which the device can be connected to a machine instrument, and the lower region being formed as a holding region (2) which comprises a part, provided as a channel (11), of a circumferentially closed or closable channel system which can be supplied with flushing liquid by means of closable supply openings (5), the bottom of the channel (11) being opened in a slot-like fashion during the sawing of the substrate block (13A, 13B) so as to provide passage openings (15) for the flushing liquid, and the channel (11) being subdivided into a plurality of sections (11A, 11B) along the device longitudinal axis (L).

2. The device according to claim 1, wherein the sections (11A, 11B) of the channel (11) along the device longitudinal axis (L) can be supplied independently of one another with flushing liquid.

3. The device according to claim 1, wherein the channel (11) is subdivided by a plurality of structurally separate channels which can be supplied independently of one another.

4. The device according to claim 1, wherein the channel (11) is subdivided by a plurality of barriers (12) fitted removably in the channel (11).

5. The device according to claim 1, wherein the closable supply openings (5) are arranged on the upper flat side (6) of the adapter region (1).

6. The device according to claim 1, wherein the closable supply openings (5) are arranged on the circumferential side (7A, 7B, 8A, 8B) of the adapter region (1).

7. The device according to claim 1, wherein the holding region (2) is formed as a holding plate (4) and the adapter region (1) is formed as an adapter plate (3), and the two plates (3, 4) are connected releasably to one another.

8. The device according to claim 1, wherein the material of the holding region (2) is selected from the group consisting of glass, plastic, epoxide, ceramic, metal and mixtures thereof.

9. A method for flushing the intermediate spaces formed by sawing a substrate block (13A, 13B) by using a device according to claim 1, wherein a flushing liquid is applied to the channel system and emerges therefrom via the passage openings (15).

10. The method according to claim 9, wherein the flushing takes place uniformly along the device longitudinal axis (L) via the passage openings (15) supplied with flushing liquid.

11. The method according to claim 9, wherein the supply of the channel (11) and the flushing of the intermediate spaces take place zonally as seen in the device longitudinal axis (L).

12. The method according to claim 9, wherein the flushing is carried out in the working region of a wafer saw.

13. The method according to claim 9, wherein the flushing is carried out in a liquid and/or with ultrasound assistance.

14. A method for flushing the intermediate spaces formed by sawing a substrate block (13A, 13B) by using a device having two regions arranged parallel to the device longitudinal axis (L) and above one another, the upper region being configured as an adapter region (1) by means of which the device can be connected to a machine instrument, and a part, provided as a channel (11) having a plurality of sections (11A, 11B) extending in the device longitudinal axis (L), of a circumferentially closed channel system being arranged in the lower region, which is formed as a holding region (2), comprising the steps:
supplying the channel system with flushing liquid by means of closable supply openings (5) arranged in the upper region; and
flushing the intermediate spaces by means of slot-like passage openings (15), which have been formed in the bottom of the channel (11) when sawing the substrate block (13A, 13B).

15. The method according to claim 14, wherein the flushing takes place uniformly along the device longitudinal axis (L) via the passage openings (15) supplied with flushing liquid.

16. The method according to claim 14, wherein the supply of the channel (11) and the flushing of the intermediate spaces take place zonally as seen in the device longitudinal axis (L).

17. The method according to claim 14, wherein the flushing is carried out in the working region of a wafer saw.

18. The method according to claim 14, wherein the flushing is carried out in a liquid and/or with ultrasound assistance.
